(19) United States
(12) Patent Application Publication
(10) Pub. No.: US 2014/0224469 A1
(43) Pub. Date: Aug. 14, 2014

(54) CONTROLLING HEAT SOURCE FLUID FOR THERMAL CYCLES

(71) Applicants: Parsa Mirmobin, La Mirada, CA (US); Dennis Strouse, Anaheim, CA (US)

(72) Inventors: Parsa Mirmobin, La Mirada, CA (US); Dennis Strouse, Anaheim, CA (US)

(73) Assignee: Access Energy LLC, Cerritos, CA (US)

(21) Appl. No.: 13/763,795

(22) Filed: Feb. 11, 2013

(51) Int. Cl. H05K 7/20; F24H 9/20

(52) U.S. Cl. CPC H05K 7/20281; F24H 9/2007
USPC 165/244; 165/297

(57) ABSTRACT

Systems, methods, and apparatuses for controlling a thermal fluid condition may include monitoring a thermal fluid at an outlet of a heat exchanger. An outlet condition of the thermal fluid at the outlet of the heat exchanger can be determined. The outlet condition of the thermal fluid can be provided to a controller of a closed-loop thermal cycle. A condition of the thermal fluid at an inlet to the heat exchanger can be adjusted based on the outlet condition of the thermal fluid.

### FIELD

The present disclosure pertains to controlling heat source fluid for thermal cycles, and more particularly to controlling a heat source fluid at the outlet of a heat exchanger based on one or more of a condition of the heat source fluid at the inlet of the heat exchanger and/or one or more operational parameters of the thermal cycle.

### BACKGROUND

In many thermal cycle applications a heat source is used that is part of a larger plant process. The condition of this heat source after exiting the thermal cycle heat exchanger can affect the overall plant performance. By providing supervisory control centered on the exit condition of the heat source a cost effective method is realized without a need to add additional costly balance of plant equipment.

### SUMMARY

Aspects of the present disclosure pertain to systems, methods, and apparatuses for controlling a thermal fluid condition. A thermal fluid condition can be monitored at an outlet of a heat exchanger. An outlet condition of the thermal fluid at the outlet of the heat exchanger can be determined. The outlet condition of the thermal fluid can be provided to a controller of a closed-loop thermal cycle.

Certain aspects of the present disclosure involve a heat exchanger configured to transfer heat between a thermal fluid and a working fluid of a closed-loop thermal cycle. A thermal fluid condition monitoring apparatus can be configured to monitor a condition of the thermal fluid at an outlet side of the heat exchanger, the heat source fluid condition monitoring apparatus configured to monitor a condition of the heat source fluid. A controller can be configured to receive thermal fluid condition information and control one or more operational parameters of the closed-loop thermal cycle based on the thermal fluid condition.

Certain aspects of the present disclosure are directed to systems, methods, and apparatuses for controlling multiple thermal fluid conditions. A first thermal fluid can be monitored at an outlet of a first heat exchanger. A second thermal fluid can be monitored at an outlet of a second heat exchanger. The outlet conditions of the first and second thermal fluids at the outlets of the respective first and second heat exchangers can be determined. The outlet conditions of the thermal fluids can be provided to a controller of a closed-loop thermal cycle. A condition of at least one of the first or second thermal fluids at an inlet to the respective first or second heat exchangers can be adjusted based on the outlet condition of the thermal fluids.

In certain implementations, adjusting the condition of the thermal fluid may include adjusting a valve upstream of the inlet to the heat exchanger, the valve controlling an amount of thermal fluid that enters the heat exchanger.

Certain implementations also may include monitoring an electrical output of the closed-loop thermal cycle. The condition of the thermal fluid at an inlet to the heat exchanger can be adjusted based in part on the electrical output of the closed-loop cycle.

Certain implementations may also include adjusting one or more operational parameters of the closed-loop thermal cycle.

In certain implementations, the one or more operational parameters of the closed-loop thermal cycle includes a mass flow rate of a working fluid of the closed-loop thermal cycle.

Certain implementations may also include monitoring an electrical output from an electric machine of the closed-loop thermal cycle and directing at least a portion of the working fluid around the electric machine based on the electrical output from the electric machine or from the power electronics.

In certain implementations, the heat exchanger is an evaporator.

In certain implementations, the heat exchanger is a condenser.

Certain implementations may also include directing the working fluid around the heat exchanger based on the condition of the thermal fluid. For example, some or all of the working fluid can be directed around the turbine expander of the electric machine so as to affect the rotation of the turbine expander.

Certain implementations may include an electric machine apparatus configured to receive the thermal cycle working fluid and generate electric power based on receiving the thermal cycle working fluid.

Certain implementations may include a bypass valve upstream of the electric machine apparatus, the bypass valve configured to direct at least a portion of the working fluid around the electric machine apparatus.

In certain implementations, the controller is configured to control the bypass valve to direct the at least a portion of the working fluid based on one or more of the electric power generated by the electric machine apparatus, a condition of the working fluid, or a condition of the thermal fluid.

In certain implementations, the controller is configured to control a pump of the closed-loop thermal cycle to adjust a mass flow rate of the working fluid.

In certain implementations, the controller is configured to receive a mass flow rate indication from a pump of the closed-loop thermal cycle.

In certain implementations, the thermal fluid condition monitoring apparatus is configured to monitor one or both of a thermal fluid temperature or a thermal fluid pressure.

Certain aspects of the implementations may include a fluid condition monitoring apparatus at an outlet of the heat exchanger configured to monitor one or both of a temperature or pressure of the working fluid of the closed-loop thermal cycle.

Certain implementations may include a bypass valve upstream of the heat exchanger, the bypass valve configured to direct the working fluid through a bypass line on the closed-loop thermal cycle around the heat exchanger based on the condition of the thermal fluid at the outlet side of the heat exchanger, wherein the bypass valve is controlled by the controller.

In certain implementations, the controller is configured to control a valve upstream of the heat exchanger, the valve controlling an amount of thermal fluid that can enter the heat exchanger.

In certain implementations, adjusting the condition of the thermal fluid comprises adjusting valves upstream of the inlet to the heat exchangers, the valves controlling an amount of thermal fluid that enters each heat exchanger.

Certain implementations may also include monitoring an electrical output of the closed-loop thermal cycle. Adjusting the condition of a thermal fluid at an inlet to a heat exchanger may be based in part on the electrical output of the closed-loop cycle.

Certain implementations may also include adjusting one or more operational parameters of the closed-loop thermal cycle.

In some implementations, the one or more operational parameters of the closed-loop thermal cycle includes a mass flow rate of a working fluid of the closed-loop thermal cycle.

Aspects of the present provide a low-cost way to monitor and control the state of a heat stream as it exits an evaporator of a closed-loop thermal cycle without a need for additional, expensive, plant equipment. Furthermore, closed-loop thermal cycle control can be devised so as to optimize the heat stream exit condition as a primary output with the ORC power output as a secondary output. The closed-loop thermal cycle control can also be configured to achieve an optimal proportion of thermal fluid exit condition and closed-loop thermal cycle output power.

### BRIEF DESCRIPTION OF THE DRAWINGS

FIG. 1A is a schematic diagram of an example thermal cycle.

FIG. 1B is a schematic diagram of an example Rankine Cycle system illustrating example Rankine Cycle system components.

FIG. 2 is a schematic diagram of an example closed-loop thermal cycle that includes heat source fluid condition monitoring sensors and working fluid condition monitoring sensors.

FIG. 3 is a process flow diagram of an example process for controlling heat source fluid conditions using closed-loop thermal cycle parameters.

FIG. 4 is a process flow diagram for determining the thermal fluid quality based on system enthalpies.

FIG. 5 is a schematic diagram of an example closed-loop thermal cycle that includes a plurality of heat sources, heat source fluid condition monitoring sensors, working fluid condition monitoring sensors.

FIG. 6 is a process flow diagram for controlling a bypass in a closed-loop thermal cycle.

Like reference numbers denote like components.

### DETAILED DESCRIPTION

The disclosure describes controlling heat source fluid for thermal cycles. For example, the heat source fluid conditions (e.g., flow rate, temperature, pressure, etc.) can be controlled at the inlet of a heat exchanger based on one or more of a condition of the heat source fluid at the outlet of the heat exchanger and/or one or more operational parameters of the thermal cycle. Similarly, thermal cycle operational parameters can be adjusted to adjust the heat transferred between the heat source fluid and the thermal cycle working fluid. All descriptions provided equally apply to monitoring and controlling of heat sink (coolant) fluid conditions as well as multiple heat sources and heat sinks.

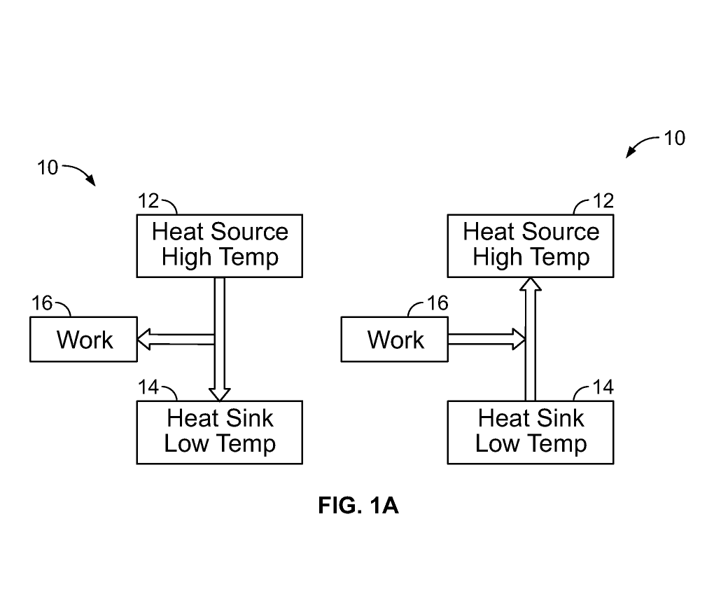

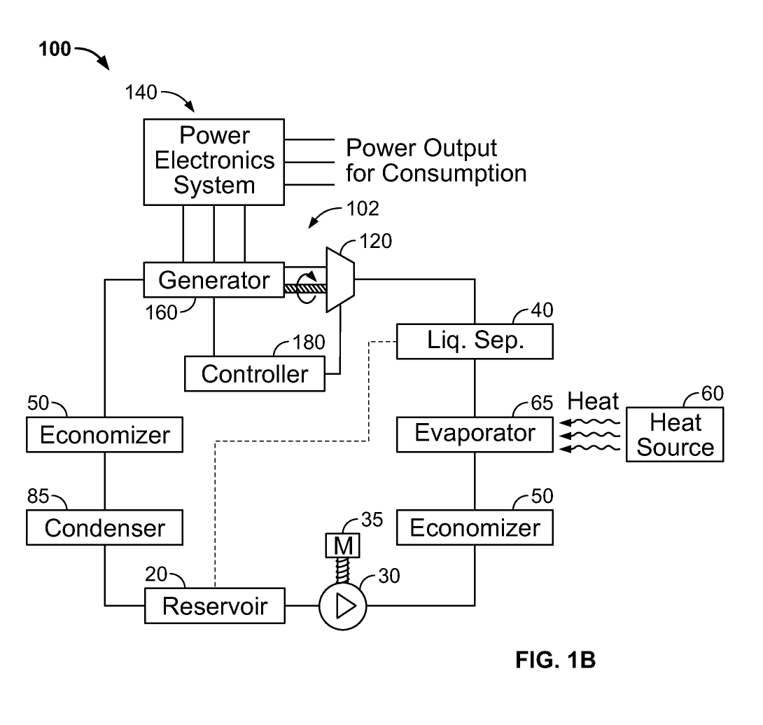

FIG. 1A is a schematic diagram of an example thermal cycle 10. The cycle includes a heat source 12 and a heat sink 14. The heat source temperature is greater than heat sink temperature. Flow of heat from the heat source 12 to heat sink 14 is accompanied by extraction of heat and/or work 16 from the system. Conversely, flow of heat from heat sink 14 to heat source 12 is achieved by application of heat and/or work 16 to the system. Extraction of heat from the heat source 12 or application of heat to heat sink 14 is achieved through a heat exchanging mechanism. Systems and apparatus described in this disclosure are applicable to any heat sink 14 or heat source 12 irrespective of the thermal cycle. For descriptive purposes, a Rankine Cycle (or Organic Rankine Cycle) is described by way of illustration, though it is understood that the Rankine Cycle is an example thermal cycle, and this disclosure contemplates other thermal cycles. Other thermal cycles within the scope of this disclosure include, but are not limited to, Sterling cycles, Brayton cycles, Kalina cycles, etc.

FIG. 1B is a schematic diagram of an example Rankine Cycle system 100 illustrating example Rankine Cycle system components. Elements of the Rankine Cycle 100 may be integrated into any waste heat recovery system. The Rankine Cycle 100 may be an Organic Rankine Cycle (“Rankine Cycle”), which uses an engineered working fluid to receive waste heat from another process, such as, for example, from the heat source plant that the Rankine Cycle system components are integrated into. In certain instances, the working fluid may be a refrigerant (e.g., an HFC, CFC, HCFC, ammonia, water, R245fa, or other refrigerant). In some circumstances, the working fluid in thermal cycle 100 may include a high molecular mass organic fluid that is selected to efficiently receive heat from relatively low temperature heat sources. As such, the turbine generator apparatus 102 can be used to recover waste heat and to convert the recovered waste heat into electrical energy.

In certain instances, the turbine generator apparatus 102 includes a turbine expander 120 and a generator 160. The turbine generator apparatus 102 can be used to convert heat energy from a heat source into kinetic energy (e.g., rotation of the rotor), which is then converted into electrical energy. The turbine expander 120 is configured to receive heated and pressurized gas, which causes the turbine expander 120 to rotate (and expand/cool the gas passing through the turbine expander 120). Turbine expander 120 is coupled to a rotor of generator 160 using, for example, a common shaft or a shaft connected by a gear box. The rotation of the turbine expander 120 causes the shaft to rotate, which in-turn, causes the rotor of generator 160 to rotate. The rotor rotates within a stator to generate electrical power. For example, the turbine generator apparatus 102 may output electrical power that is configured by a power electronics package to be in form of 3-phase 60 Hz power at a voltage of about 400 VAC to about 480 VAC. Alternative embodiments may output electrical power at different power and/or voltages. Such electrical power can be transferred to a power electronics system 140, other electrical driven components within or outside the engine compressor system and, in certain instances, to an electrical power grid system. Turbine may be an axial, radial, screw or other type turbine. The gas outlet from the turbine expander 120 may be coupled to the generator 160, which may receive the gas from the turbine expander 120 to cool the generator components.

The power electronics 140 can operate in conjunction with the generator 160 to provide power at fixed and/or variable voltages and fixed and/or variable frequencies. Such power can be delivered to a power conversion device configured to provide power at fixed and/or variable voltages and/or frequencies to be used in the system, distributed externally, or sent to a grid.

Rankine Cycle 100 may include a pump device 30 that pumps the working fluid. The pump device 30 may be coupled to a liquid reservoir 20 that contains the working fluid, and a pump motor 35 can be used to operate the pump. The pump device 30 may be used to convey the working fluid to a heat exchanger 65 (the term “heat exchanger” will be understood to mean one or both of an evaporator or a heat exchanger). The heat exchanger 65 may receive heat from a heat source 60, such as a waste heat source from one or more heat sources. In such circumstances, the working fluid may be directly heated or may be heated in a heat exchanger in which the working fluid receives heat from a byproduct fluid of the process. In certain instances, the working fluid can cycle through the heat source 60 so that at least a substantial portion of the fluid is converted into gaseous state. Heat source 60 may also indirectly heat the working fluid with a thermal fluid that carries heat from the heat source 60 to the evaporator 65. Some examples of a thermal fluid include water, steam, thermal oil, etc.

Rankine Cycle 100 may include a bypass 250 that allows the working fluid to partially or wholly bypass the turbine expander 120. The bypass can be used in conjunction with or isolated from the pump device 30 to control the condition of working fluid around the closed loop thermal cycle. The bypass line can be controlled by inputs from the controller 180. For example, in some instances, the bypass can be used to control the output power from the generator by bypassing a portion of the working fluid from entering the turbine expander 120.

Typically, working fluid at a low temperature and high pressure liquid phase from the pump device 30 is circulated into one side of the economizer 50, while working fluid that has been expanded by a turbine upstream of a condenser heat exchanger 85 is at a high temperature and low pressure vapor phase and is circulated into another side of the economizer 50 with the two sides being thermally coupled to facilitate heat transfer there between. Although illustrated as separate components, the economizer 50 (if used) may be any type of heat exchange device, such as, for example, a plate and frame heat exchanger, a shell and tube heat exchanger or other device.

The evaporator/preheater heat exchanger 65 may receive the working fluid from the economizer 50 at one side and receive a supply of thermal fluid (that is (or is from) the heat source 60) at another side, with the two sides of the evaporator/preheater heat exchanger 65 being thermally coupled to facilitate heat exchange between the thermal fluid and working fluid. For instance, the working fluid enters the evaporator/preheater heat exchanger 65 from the economizer 50 in liquid phase and is changed to a vapor phase by heat exchange with the thermal fluid supply. The evaporator/preheater heat exchanger 65 may be any type of heat exchange device, such as, for example, a plate and frame heat exchanger, a shell and tube heat exchanger or other device.

In certain instances of the Rankine Cycle 100, the working fluid may flow from the outlet conduit of the turbine generator apparatus 102 to a condenser heat exchanger 85. The condenser heat exchanger 85 is used to remove heat from the working fluid so that all or a substantial portion of the working fluid is converted to a liquid state. In certain instances, a forced cooling airflow or water flow is provided over the working fluid conduit or the condenser heat exchanger 85 to facilitate heat removal. After the working fluid exits the condenser heat exchanger 85, the fluid may return to the liquid reservoir 20 where it is prepared to flow again though the Rankine Cycle 100. In certain instances, the working fluid exits the generator 160 (or in some instances, exits a turbine expander 120) and enters the economizer 50 before entering the condenser heat exchanger 85.

Liquid separator 40 (if used) may be arranged upstream of the turbine generator apparatus 102 so as to separate and remove a substantial portion of any liquid state droplets or slugs of working fluid that might otherwise pass into the turbine generator apparatus 102. Accordingly, in certain instances of the embodiments, the gaseous state working fluid can be passed to the turbine generator apparatus 102, while a substantial portion of any liquid-state droplets or slugs are removed and returned to the liquid reservoir 20. In certain instances of the embodiments, a liquid separator may be located between turbine stages (e.g., between the first turbine wheel and the second turbine wheel, for multi-stage expanders) to remove liquid state droplets or slugs that may form from the expansion of the working fluid from the first turbine stage. This liquid separator may be in addition to the liquid separator located upstream of the turbine apparatus.

Controller 180 may provide operational controls for the various cycle components, including the heat exchangers and the turbine generator.

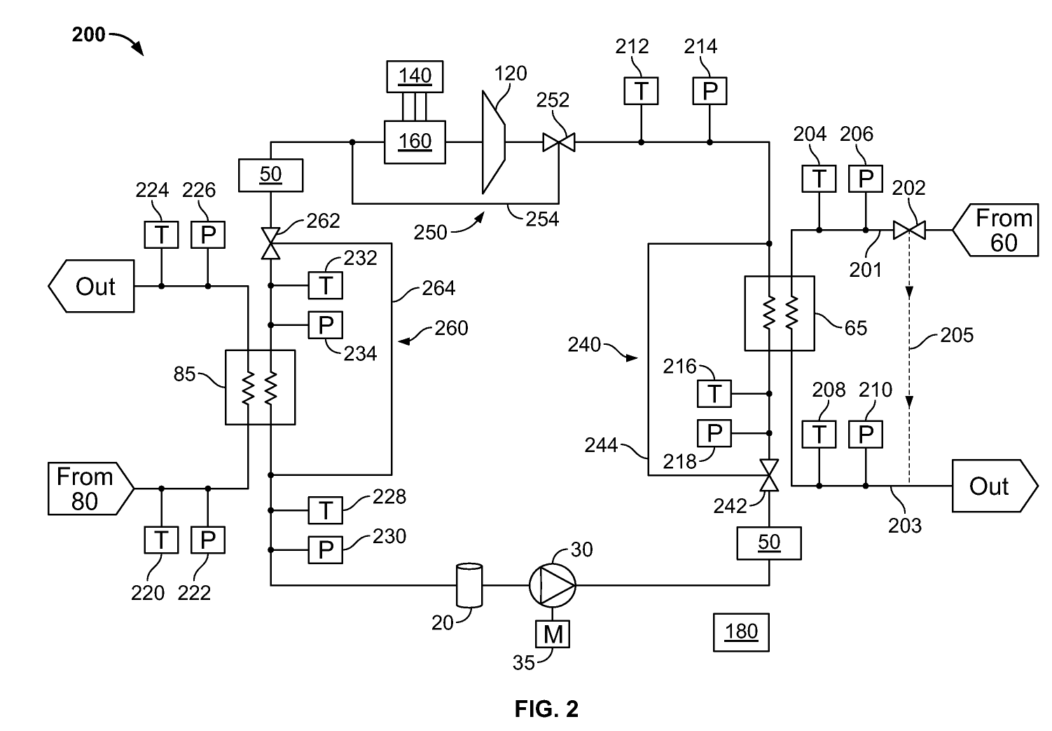

FIG. 2 is a schematic diagram of an example closed-loop thermal cycle 200 that includes heat source fluid condition monitoring sensors and working fluid condition monitoring sensors. The example closed-loop thermal cycle 200 shown in FIG. 2 is similar to that shown in FIG. 1B, and like reference numerals refer to like structural features. Furthermore the absence of a structural feature from either FIG. 1B or FIG. 2 is for illustrative purposes and is not meant to limit either figure to what is shown. Put differently, this disclosure contemplates that the features shown in FIG. 1B can be included in the closed-loop thermal cycle 200 shown in FIG. 2 and vice versa.

For example, closed-loop thermal cycle 200 includes a heat exchanger 65 (shown as an evaporator). The heat exchanger 65 can receive heat from a thermal fluid from a heat source 60 on heat source input line 201. The heat source can be any source of heat, including hot waste fluid from another process. Additionally, the heat exchanger 65 can receive heat directly from a thermal fluid of the heat source 60 or the thermal fluid may be heated indirectly by the heat source 60. The heat source input line 201 from the heat source 60 includes a heat source control valve 202 upstream of the heat exchanger 65. The heat source control valve 202 can be controlled by electric input from the controller 180. The heat source control valve 202 can cut off thermal fluid from entering the heat exchanger 65. In some implementations, heat source control valve 202 can be a three-way valve and direct some or all of the thermal fluid through a bypass line 205.

One or more thermal fluid condition sensors (or monitors) can be located upstream of the heat exchanger 65 on the thermal fluid input line 201. The thermal fluid condition sensors can include a temperature sensor 204 and/or a pressure sensor 206. The temperature sensor 204 and/or the pressure sensor 206 can monitor the thermal fluid condition (one or both of temperature and pressure can be included when referring to the thermal fluid condition and the working fluid condition). The sensors can output their readings to the controller 180. In the illustrated example, the working fluid can be monitored upstream of the heat exchanger 65 by temperature sensor 216 and/or pressure sensor 218. Working fluid sensors can also be located at the outlet side of the heat exchanger 65, such as temperature sensor 212 and pressure sensor 214.

The working fluid can also be monitored upstream and downstream of the condenser heat exchanger 85. For example, the working fluid condition can be monitored upstream of the condenser using temperature sensor 232 and pressure sensor 234. The working fluid condition can be monitored downstream of the condenser using temperature sensor 228 and pressure sensor 230. The condenser heat transfer fluid can also be monitored upstream (temperature sensor 220 and pressure sensor 222) and downstream (temperature sensor 224 and pressure sensor 226) of the condenser. Each of the temperature sensors and pressure sensors can output signals indicating the respective conditions to the controller 180. The condenser heat transfer fluid can be controlled by controller 180. The condenser heat transfer fluid can be controlled by one or more mechanisms associated with the coolant fluid source 80 (e.g. heat sink 80), such as a fan, a pump, a valve, or some combination thereof. The coolant fluid and the heat source fluid can both be referred to as a thermal fluid.

One or more thermal fluid condition sensors can also be located downstream of the heat exchanger 65 on the thermal fluid output line 203. For example, a temperature sensor 208 and/or a pressure sensor 210 can be located downstream of the heat exchanger 65. These thermal fluid condition sensors can be used to monitor the thermal fluid conditions at the outlet side of the heat exchanger 65. The thermal fluid condition at the outlet side of the heat exchanger 65 can be used to infer the condition of the heat source. The controller 180 can alter the conditions of the closed-loop thermal cycle 200, as well as other conditions, in order to change the heat source fluid quality as needed.

As an illustrative example, a problem encountered with steam heat sources is the nature of fluid stream in the condensate line. Plant equipment to accommodate steam only or condensate only streams are readily available; however, a stream with poor quality steam is difficult and expensive to process. The inlet steam temperature and pressure are also being monitored in order to control the heat source control valve. By adding sensors to monitor the steam temperature and pressure at the exit of the heat exchanger 65, the condition of the heat source thermal fluid at the exit of the heat exchanger 65 can be inferred. In a case where the closed-loop thermal cycle 200 is producing maximum (or desired) electrical power but is not utilizing all the heat from the thermal fluid, the exit condition of the heat source can be considered to be a poor quality steam. Using this steam condition as an input condition to the controller 180, the heat source control valve 202 can be instructed to close until all the steam is condensed at the exit of the heat exchanger while maintaining maximum (or desired) ORC electrical power output.

In another illustrative example, the controller 180 can use the thermal fluid conditions at the outlet side of the heat exchanger to alter the mass flow rate of the working fluid by, for example, controlling the pump 30 to pump working fluid at a different rate. The relationships between the heat source thermal fluid and the working fluid can be considered in terms of enthalpy: the enthalpy of the thermal fluid prior to entering the heat exchanger 65 is a function of the temperature and pressure of the thermal fluid at that point: Hs(1)=fs(T1, P1). Likewise, the enthalpy of the thermal fluid at the outlet side of the heat exchanger can be written as Hs(2)=fs(T2, P2). The enthalpy of the working fluid at the outlet side of the heat exchanger 65 can be written as Hr(3)=fr(T3, P3), and the enthalpy of the working fluid at the inlet side of the heat exchanger 65 can be written as Hr(4)=fr(T4, P4). The enthalpy Hs(2) can be found based on the other enthalpies: Hs(2)=Hs(1)−((dmr/dt)/(dms/dt))*(Hr(4)−Hr(3)), where dmr/dt is the mass flow rate of the working fluid and dms/dt is the mass flow rate of the thermal fluid. The quality of the thermal source can be Q=(Hs(2)−HsL)/(HsG−HsL), where HsL is the enthalpy of an all-liquid thermal fluid (enthalpy of saturated liquid) and HsG is the enthalpy of an all-gas thermal fluid (enthalpy of saturated gas). HsL and HsG can be a known value or can be calculated theoretically based on the nature of the thermal fluid.

The closed-loop thermal cycle can include a bypass 240. The bypass 240 can allow the working fluid to bypass the heat exchanger 65. A bypass valve 242 can be located upstream from the heat exchanger and can be controlled by the controller 180. Based on working fluid conditions, thermal fluid conditions, and/or power output by generator 160, the controller 180 can control the bypass valve 242 to direct some or all of the working fluid through bypass line 244.

Similarly, a bypass 260 can allow some or all of the working fluid to bypass the condenser heat exchanger 85. A bypass valve 262 can be controlled by controller 180 to direct some or all of the working fluid through bypass line 264.

The thermal cycle system 200 can also include a bypass 250 that allows the working fluid to bypass the turbine expander 120. The bypass 250 includes a bypass valve 252 that can direct some or all of the working fluid through bypass line 254. The bypass valve 252 can be controlled by the controller 180. For example, the controller 180 can receive information about the output power of the generator 160 and change the amount of working fluid that enters the turbine expander 120. Similarly, the controller 180 can be informed of the condition of the working fluid and the controller 180 can control the bypass valve 252 to redirect some or all of the working fluid through the bypass 250.

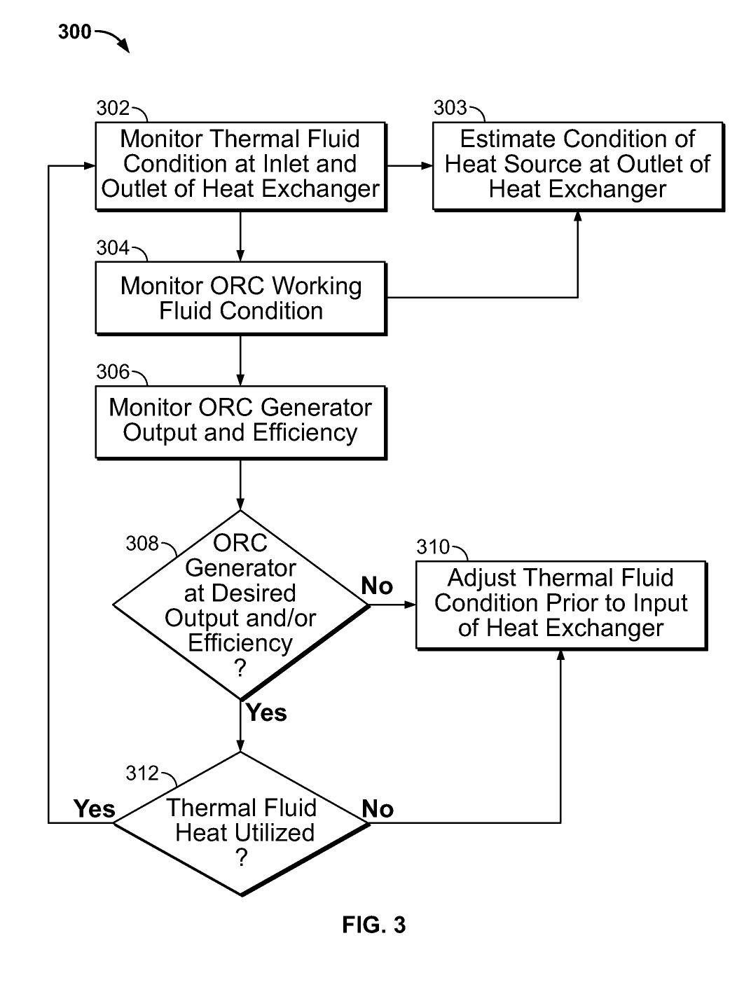

FIG. 3 is a process flow diagram 300 of an example process for controlling heat source fluid conditions using closed-loop thermal cycle parameters. The thermal fluid condition(s) at the outlet of a closed-loop thermal cycle heat exchanger (302). The thermal fluid condition(s) can also be monitored at the inlet side of the heat exchanger. The thermal fluid conditions can include the temperature of the thermal fluid and/or the pressure of the thermal fluid. Based on the condition of the thermal fluid at the outlet side of the heat exchanger, the thermal source condition can be estimated (303).

In some implementations, the generator output and/or efficiency can be monitored (306). It can be determined whether the generator is operating at a desired output or efficiency (308). If the generator is not operating at a desired output or efficiency, then the thermal fluid condition can be adjusted before it enters the heat exchanger (310). For example, the mass flow rate of the thermal fluid can be changed to adjust the temperature of the working fluid.

It can also be determined whether the thermal fluid heat is being utilized efficiently (312). In some instances, there may be residual heat left in the thermal fluid after the thermal fluid passes through the heat exchanger. In instances when the generator is operating at a desired output and efficiency, the residual heat in the thermal fluid can indicate a poor quality thermal fluid. The thermal fluid condition can be adjusted before it enters the heat exchanger (310). For example, a heat source control valve upstream of the heat exchanger can be closed so that the thermal fluid that is passing through the heat exchanger can transfer its heat to the working fluid. Additionally, in situations where the thermal fluid is steam, closing the heat source control valve can allow the steam to condense at the outlet of the heat exchanger. In circumstances where the heat source cannot process poor quality steam, allowing the steam to condense allows the heat source to better process the thermal fluid.

In some implementations, the condition(s) of the working fluid of the closed-loop thermal cycle can be monitored (304). Specifically, the temperature and/or pressure of the working fluid can be monitored at the outlet side of the heat exchanger. The working fluid can be monitored at the outlet side of the heat exchanger to provide an indication of the thermal fluid condition. The thermal fluid can be adjusted based on the inferred condition of the thermal fluid (303).

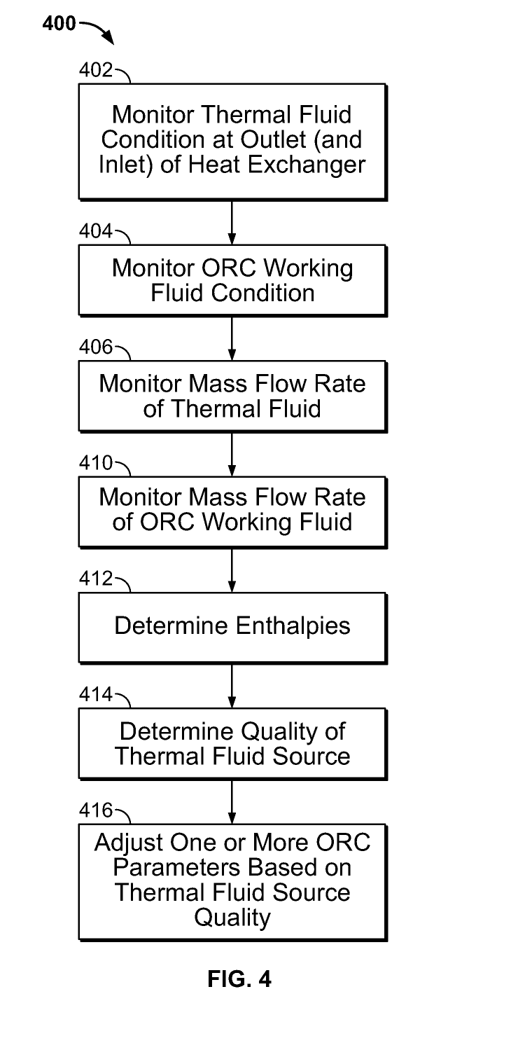

FIG. 4 is a process flow diagram 400 for determining the thermal fluid quality based on system enthalpies. Thermal fluid conditions (temperature, pressure, etc.) can be monitored at the outlet of a heat exchanger (402). The working fluid conditions can also be monitored (404). The mass flow rate of the thermal fluid can be monitored (406). The working fluid mass flow rate can also be monitored (408). The system enthalpies can be determined (412). For example, the above enthalpy equations can be used to determine the enthalpy of the thermal fluid at the outlet side of the heat exchanger. Based on the enthalpies, the quality of the thermal fluid source can be calculated (414). One or more closed-loop thermal cycle parameters can be adjusted (416). For example, because the enthalpy of the thermal fluid at the outlet side of the heat exchanger depends on the mass flow rate of the working fluid and the thermal fluid, one or both can be adjusted to achieve a different quality measurement.

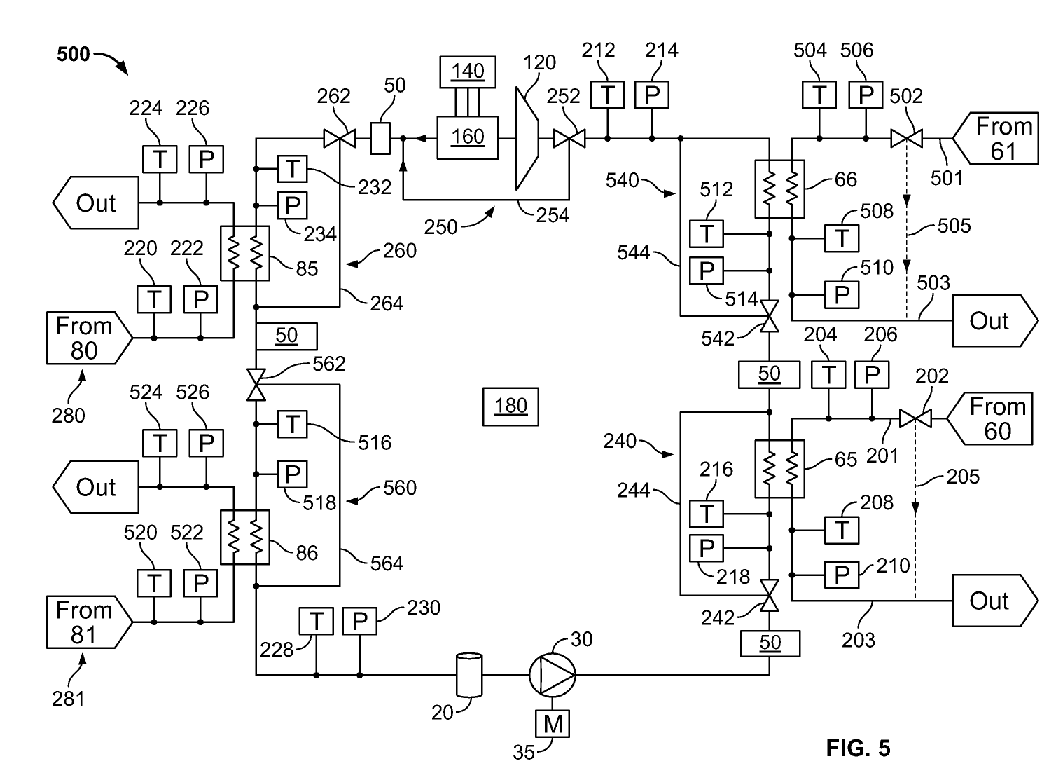

FIG. 5 is a schematic diagram of an example closed-loop thermal cycle 500 that includes a plurality of heat sources, heat source fluid condition monitoring sensors, working fluid condition monitoring sensors. Closed-loop thermal cycle 500 shares many of the same features as the closed-loop thermal cycle 200 described above and shown in FIG. 2. The closed-loop thermal cycle 500 includes a second heat source 61 connected upstream of the electric machine turbine wheel 120. The second heat source 61 can transfer heat to a working fluid across heat exchanger 66. A thermal fluid condition monitor can be upstream of the heat exchanger 66 on the thermal fluid input line 501. The thermal fluid condition monitor can include a temperature monitor 504 and a pressure monitor 506. A temperature monitor 508 and pressure monitor 510 can also be located downstream of the heat exchanger 66 on the thermal fluid output line 503. The condition of the thermal fluid before and after the heat exchanger 66 can be provided to controller 180. A valve 502 can be located on the input line 501 upstream of the heat exchanger. Valve 502 can be controlled by the controller 180 based on the thermal fluid condition. For example, the controller can control the valve to open or close (thereby permitting all, some, or none of the thermal fluid to enter the heat exchanger 66) based on the thermal fluid condition at the outlet of the heat exchanger 66. The valve 502 can be closed to prevent thermal fluid from entering the heat exchanger 66. In some implementations, a bypass line 505 can be included, and the valve 502 can be a three-way valve that redirects some or all of the thermal fluid to the outlet line 503.

Additionally a bypass 540 can permit working fluid to bypass the heat exchanger 66. The bypass 540 includes a bypass valve 542 and a bypass line 544. The bypass valve 542 can be controlled by controller 180 to permit all, some, or none of the working fluid to enter the heat exchanger. The controller 180 can receive working fluid condition information from one or more than one of the working fluid condition monitors. For example, the controller can receive working fluid temperature information and/or pressure information from temperature monitor 212 and pressure monitor 214 that monitor the working fluid condition prior to entry into the turbine expander 120; or controller 180 can receive working fluid temperature and/or pressure information of the working fluid prior to entry into the heat exchanger 66 from temperature monitor 512 and pressure monitor 514. Thermal fluid conditions can also be provided to the controller 180. For example, the temperature and/or pressure of the thermal fluid prior to entry into the heat exchanger 66 can be provided to the controller 180 from temperature monitor 504 and pressure monitor 506. The temperature and/or pressure of the thermal fluid after exit from the heat exchanger 66 can be provided to the controller 180 from temperature monitor 508 and pressure monitor 510.

The controller 180 can receive temperature and pressure conditions of the thermal fluids from both heat sources 60 and 61. Accordingly, the controller 180 can selectively control bypass 240 and bypass 540 to direct the working fluid. For example, if heat source 61 provides a better steam than heat source 60, the controller 180 may control the valves 242 and 542 to direct the working fluid to bypass heat exchanger 65 and enter heat exchanger 66. The bypass may occur instead of or in addition to closing heat source control valve 202. By leaving heat source control valve 202 open, bad steam can be purged from the heat source inlet line 201. If heat source 60 starts producing better steam, then the controller 180 can control valve 242 to open, if needed. In this example, the controller 180 can receive a plurality of fluid condition information and output control signals to a plurality of points in the system to selectively direct either or both of the working fluid or the thermal fluid.

Similarly, the closed-loop thermal cycle 500 can be connected a second heat sink 81. The second heat sink 81 can be used to transfer heat between a heat transfer fluid and the working fluid across condenser 86. A heat transfer fluid condition monitor can be upstream of the condenser 86. The heat transfer fluid condition monitor can include a temperature monitor 520 and a pressure monitor 522. A temperature monitor 524 and pressure monitor 526 can also be located downstream of the condenser 86. The condition of the heat transfer fluid before and after the condenser 86 can be provided to controller 180. For example, the controller can control the heat sink to selectively alter the mass flow rate and/or temperature of the heat transfer fluid based on its conditions, or based on the conditions of the working fluid. The working fluid can be monitored at temperature monitor 516 and pressure monitor 518 upstream of the condenser 86, and by temperature monitor 228 and pressure monitor 230 downstream of condenser 86. The controller 180 is thus in communication with heat sink 81 and can send commands to it accordingly.

Additionally a bypass 560 can permit working fluid to bypass the condenser 86. The bypass 560 includes a bypass valve 562 and a bypass line 564. The bypass valve 562 can be controlled by controller 180 to permit all, some, or none of the working fluid to enter the heat exchanger. The controller 180 can receive working fluid condition information from one or more than one of the working fluid condition monitors. For example, the controller can receive working fluid temperature information and/or pressure information from temperature monitor 516 and pressure monitor 518 that monitor the working fluid condition prior to entry into the condenser 86; or controller 180 can receive working fluid temperature and/or pressure information of the working fluid after exiting condenser 86 from temperature monitor 228 and pressure monitor 230. Heat transfer fluid conditions can also be provided to the controller 180. For example, the temperature and/or pressure of the heat transfer fluid prior to entry into the condenser 86 can be provided to the controller 180 from temperature monitor 520 and pressure monitor 522. The temperature and/or pressure of the heat transfer fluid after exit from the condenser 86 can be provided to the controller 180 from temperature monitor 524 and pressure monitor 526.

The controller 180 can receive temperature and pressure conditions of the heat transfer fluids from both condensers 85 and 86, respectively. Accordingly, the controller 180 can selectively control bypass 260 and bypass 560 to direct the working fluid. For example, the controller 180 can selectively open or close valve 262 and/or 562 to redirect the working fluid based on working fluid conditions and/or heat transfer fluid conditions from any point in the closed-loop thermal cycle system (including from points on heat transfer fluid lines).

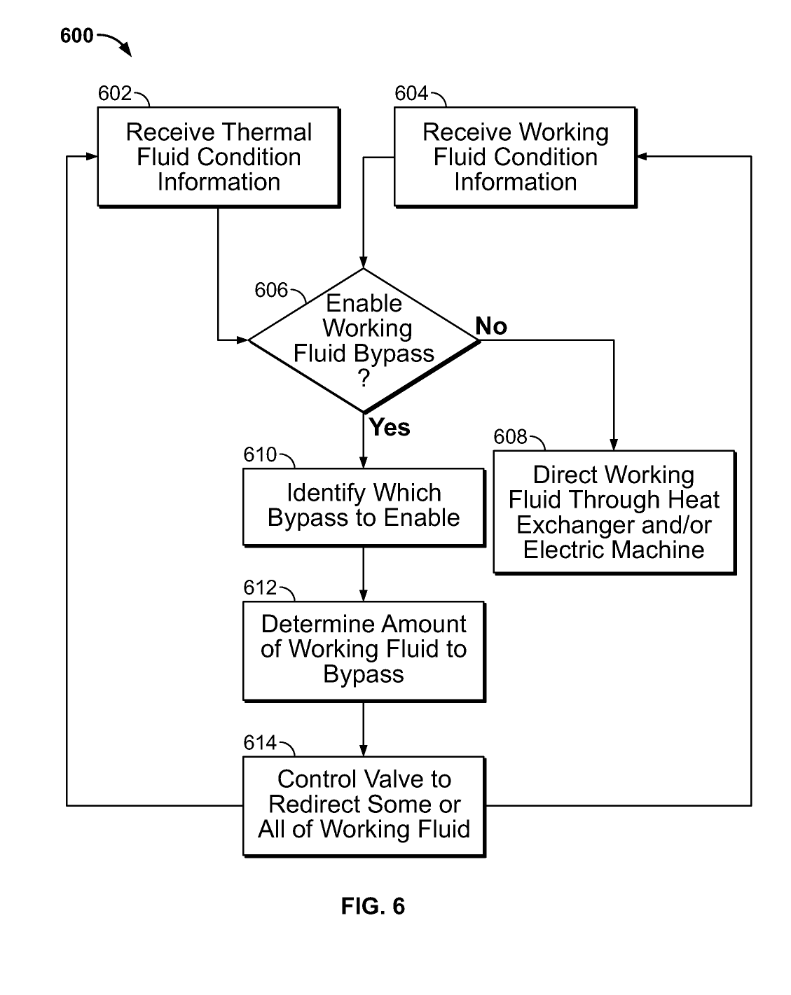

FIG. 6 is a process flow diagram 600 for controlling a bypass in a closed-loop thermal cycle. As described above, a bypass can be included to direct the working fluid around the heat exchanger (either or both the evaporator and/or condenser). The bypass can be controlled by a controller, which can control the bypass based on inputs from any number of sources. For example, the bypass can be actuated based on working fluid conditions and/or thermal fluid conditions. For example, the controller can receive thermal fluid condition information (602). Additionally, or alternatively, the controller can receive working fluid condition information (604). Based on the received condition information, the controller can determine whether to actuate one or more working fluid bypasses (606). The working fluid bypasses can allow the working fluid to bypass components of the closed-loop thermal cycle, such as one or more heat exchangers and/or an electric machine (e.g., an electric machine that includes a turbine expander and a rotor and stator for generating electrical power). The working fluid can also be directed around the electric machine (or components thereof) based on the electrical output from the electric machine or from the electrical output of the power electronics (or, generally, the condition of the electrical power produced by the closed-loop thermal cycle).

If the controller determines that the working fluid should not bypass the closed-loop thermal cycle, the controller controls the bypass valves to direct the working fluid into the appropriate component (608). If the controller determines that the working fluid can bypass the component, the controller can first determine which bypass to enable (610). The controller can also determine how much of the working fluid to divert (612). For example, some or all of the working fluid can be diverted. The controller can then send a control signal to one or more valve to redirect the working fluid (614). The cycle can then repeat.

The above process flow can be applied to implementations involving one or more than one heat sources and/or one or more than one heat sinks.

A number of embodiments have been described. Nevertheless, it will be understood that various modifications may be made. Accordingly, other embodiments are within the scope of the following claims:

What is claimed is:

1. A method for controlling a thermal fluid condition, the method comprising:
monitoring a thermal fluid at an outlet of a heat exchanger;
determining an outlet condition of the thermal fluid at the outlet of the heat exchanger;
providing the outlet condition of the thermal fluid to a controller of a closed-loop thermal cycle; and
adjusting a condition of the thermal fluid at an inlet to the heat exchanger based on the outlet condition of the thermal fluid.

2. The method of claim 1, wherein adjusting the condition of the thermal fluid comprises adjusting a valve upstream of the inlet to the heat exchanger, the valve controlling an amount of thermal fluid that enters the heat exchanger.

3. The method of claim 1, further comprising:
monitoring an electrical output of the closed-loop thermal cycle; and
wherein adjusting the condition of the thermal fluid at an inlet to the heat exchanger is based in part on the electrical output of the closed-loop cycle.

4. The method of claim 1, further comprising adjusting one or more operational parameters of the closed-loop thermal cycle.

5. The method of claim 4, wherein the one or more operational parameters of the closed-loop thermal cycle includes a mass flow rate of a working fluid of the closed-loop thermal cycle.

6. The method of claim 1, further comprising:
monitoring an electrical output from an electric machine of the closed-loop thermal cycle; and
directing at least a portion of the working fluid around the electric machine based on the electrical output from the electric machine.

7. The method of claim 1, wherein the heat exchanger is an evaporator.

8. The method of claim 1, wherein the heat exchanger is a condenser.

9. The method of claim 1, further comprising directing the working fluid around the heat exchanger based on the condition of the thermal fluid.

10. A system comprising:
a heat exchanger configured to transfer heat between a thermal fluid and a working fluid of a closed-loop thermal cycle;
a thermal fluid condition monitoring apparatus configured to monitor a condition of the thermal fluid at an outlet side of the heat exchanger, the heat source fluid condition monitoring apparatus configured to monitor a condition of the heat source fluid; and
a controller configured to receive thermal fluid condition information and control one or more operational parameters of the closed-loop thermal cycle based on the thermal fluid condition.

11. The system of claim 10, further comprising an electric machine apparatus configured to receive the thermal cycle working fluid and generate electric power based on receiving the thermal cycle working fluid.

12. The system of claim 11, further comprising a bypass valve upstream of the electric machine apparatus, the bypass valve configured to direct at least a portion of the working fluid around the electric machine apparatus.

13. The system of claim 12, wherein the controller is configured to control the bypass valve to direct the at least a portion of the working fluid based on one or more of the electric power generated by the electric machine apparatus, a condition of the working fluid, or a condition of the thermal fluid.

14. The system of claim 10, wherein the controller is configured to control a pump of the closed-loop thermal cycle to adjust a mass flow rate of the working fluid.

15. The system of claim 10, wherein the controller is configured to receive a mass flow rate indication from a pump of the closed-loop thermal cycle.

16. The system of claim 10, wherein the thermal fluid condition monitoring apparatus is configured to monitor one or both of a thermal fluid temperature or a thermal fluid pressure.

17. The system of claim 10, further comprising a fluid condition monitoring apparatus at an outlet of the heat exchanger configured to monitor one or both of a temperature or pressure of the working fluid of the closed-loop thermal cycle.

18. The system of claim 10, further comprising a bypass valve upstream of the heat exchanger, the bypass valve configured to direct the working fluid through a bypass line on the closed-loop thermal cycle around the heat exchanger based on the condition of the thermal fluid at the outlet side of the heat exchanger, wherein the bypass valve is controlled by the controller.

19. The system of claim 10, wherein the controller is configured to control a valve upstream of the heat exchanger, the valve controlling an amount of thermal fluid that can enter the heat exchanger.

20. A method for controlling multiple thermal fluid conditions, the method comprising:
monitoring a first thermal fluid at an outlet of a first heat exchanger;
monitoring a second thermal fluid at an outlet of a second heat exchanger;
determining an outlet condition of the first and second thermal fluids at the outlets of the respective first and second heat exchangers;
providing the outlet conditions of the thermal fluids to a controller of a closed-loop thermal cycle; and
adjusting a condition of at least one of the first or second thermal fluids at an inlet to the respective first or second heat exchangers based on the outlet condition of the thermal fluids.
